(19) United States
(12) Patent Application Publication
(10) Pub. No.: US 2021/0246551 A1
(43) Pub. Date: Aug. 12, 2021

(54) SYSTEMS FOR PROCESSING WITH MEAN FREE PATH LIMITED SPECIES

(71) Applicants: Laminera LLC, Berkeley, CA (US); The Regents of the University of California, Oakland, CA (US)

(72) Inventors: Lauren M. Otto, Berkeley, CA (US); Adam M. Schwartzberg, Richmond, CA (US); Shaul Aloni, El Cerrito, CA (US); Edward K. S. Wong, Walnut Creek, CA (US); Joseph G. Wallig, Concord, CA (US)

(21) Appl. No.: 17/174,183

(22) Filed: Feb. 11, 2021

Related U.S. Application Data
(60) Provisional application No. 62/975,127, filed on Feb. 11, 2020.

(51) Int. Cl. C23C 16/455; H01J 37/32

(52) U.S. Cl. CPC C23C 16/45544; H01J 37/32715; H01J 2237/3321; H01J 37/32082; C23C 16/45536; H01J 37/32834

(57) ABSTRACT

This application relates to substrate processing systems using mean free path limited species generated in a generation region; a substrate processing chamber including a substrate support system positioned within the mean free path of the mean free path limited species; the substrate processing system having a pumping system for evacuating the contents of the substrate processing chamber; the substrate processing system optionally including a device for throttling the pumping of the substrate processing chamber and optionally including a device for mechanically tuning the distance between the emission point of the mean free path limited species and the substrate.

### CROSS-REFERENCE TO RELATED APPLICATIONS

This Application claims the benefit of U.S. Provisional Application No. 62/975,127, filed on 11 Feb. 2020, and entitled “Systems for processing with mean free path limited species,” the entire contents of which are incorporated by reference herein.

### STATEMENT OF GOVERNMENT SUPPORT

This invention was made with government support under a CRADA (FP00005818) between (Laminera LLC) and Lawrence Berkeley National Laboratory operated for the United States Department of Energy and with government support under Contract No. DE-AC02-05CH11231 awarded by the U.S. Department of Energy. The government has certain rights in this invention.

### BACKGROUND

Mean free path is defined as the average distance a gas molecule, dissociated gas atom, or other particle will travel before collision with another molecule, atom, or particle and is inversely proportional to the concentration of the gas or particles and to the cross-sectional area of the gas molecule, atom, or other particle (e.g. pressure). A mean free path limited species is a species whose travel distance or lifetime is primarily limited by its own combination or recombination with its own species or combination or recombination with another species. For instance, a dissociated gas atom that is electrically neutral could combine with another like itself upon collision resulting in a molecular gas species. In the specific case of electrically neutral atomic nitrogen, which is reactive, combining with another electrically neutral atomic nitrogen, the resulting N₂ is inert and can no longer perform, for instance, a reactive role in the desired process chemistry for an atomic layer deposition process.

Atomic layer deposition is a chemical vapor-based deposition technique that exposes the substrate sequentially to at least two different species which are reactive with each other. The sequential exposure of the at least two different reactive species occurs in a segregated manner, where the substrate is exposed to only one reactive species at a time with that species predominantly chemisorbing to the substrate surface no more than one atomic or molecular layer, and the reactive species are then sequentially alternated to build a film. One of the reactive species can be a halogen-based, organometallic, or other precursor for an element such as Si, Ti, Ta, Hf, Al, etc. and in some implementations, the other reactive species can be a reactive gas or vapor source of N, H, O, etc. such as NH₃ or H₂O, etc. Thermal assistance with the chemical reaction was also included in atomic layer deposition systems.

Later atomic layer deposition systems can replace the traditionally used reactive gas or vapor sources of N, H, O, etc. such as NH₃ or H₂O, etc. with the radicals from a plasma generated from the gases N₂, H₂, O₂, NH₃, etc. and radicals are unstable species. Radical forms of the example gases N₂, H₂, O₂, and NH₃, include but are not limited to ionized O₂, N₂, and H₂, and neutral and ionized N, H, O, O₃, NH, NH₂, etc. Suitable forms of plasma generation for plasma enhanced atomic layer deposition include but are not limited to direct coupled or capacitively coupled plasmas, inductively coupled plasmas, electron cyclotron resonance plasmas, and hollow cathode plasmas, with each technique generation a portion of different radicals including ions and neutral atomic species, electrons, and photons. These plasmas can be generated with radio frequency (RF) electromagnetic radiation at or around 13.56 MHz or another suitable frequency, and the state of the art has recognized that the use of such sources also causes “RF damage” to substrates and films. One component of “RF damage” can be understood as “RF sputtering” or ion-based damage as the ions from the plasma can be quite aggressive due to their charge imbalance. A second component of “RF damage” can be understood as charge accumulation in the film or substrate or the generation of undesirable electric currents in the substrate and its components due to excess charge from ions, electrons, or a photoelectron effect.

### BRIEF DESCRIPTION OF THE FIGURES

FIG. 1a is a drawing of a preferred embodiment of a system for processing with mean free path limited species;

FIG. 1b is a drawing of another preferred embodiment of a system for processing with mean free path limited species;

FIG. 1c is a drawing of another preferred embodiment of a system for processing with mean free path limited species;

FIG. 1d is a drawing of another preferred embodiment of a system for processing with mean free path limited species;

FIG. 2 is a three dimensional mechanical drawing of the preferred embodiment in figure is of a system for processing with mean free path limited species;

FIG. 3 is a photograph of the preferred embodiment in FIG. 1c and FIG. 2 of a system for processing with mean free path limited species; and

FIG. 4 is a photograph of the interior of the substrate processing chamber of the preferred embodiment in FIG. 1c and FIG. 2 of a system for processing with mean free path limited species.

### DESCRIPTION OF THE EMBODIMENTS

The following description of the embodiments of the invention is not intended to limit the invention to these embodiments but rather to enable a person skilled in the art to make and use this invention.

The present inventors have recognized that it can be advantageous to use predominantly the neutral atomic (or other electrically neutral radical) species as the radical of choice for substrate processing as the neutral species can avoid aggressive reactions and sputtering and also will not create electrical charging or current issues in the substrate.

This invention relates generally to substrate processing systems, and more specifically to a new and useful system for processing with mean free path limited species.

Electrically neutral radical species can be isolated from a plasma, and ions can be neutralized as the leave a plasma using a charge exchange mechanism such as a metal or ceramic aperture plate or screen that lies at or around the boundary of the plasma, the plasma sheath, or the substrate processing chamber. As such it is possible to ensure that the predominant species from the plasma that interacts with the substrate is in fact the neutral radical species. This neutral radical species has a unique difference from ions that dictates how it (they) must be handled for successful processing and chemistry. Ions' like charge causes them to repel each other upon a close encounter whereas neutral radicals will instead likely combine with each other upon a close encounter. As such, the neutral radicals lifetime for reactive opportunity with the substrate is defined by their mean free path, which is controlled by their size and the partial pressure of other species in the substrate processing chamber with which they can combine and become less reactive or unreactive. Accordingly, equipment for processing with such mean free path limited species including neutral radicals (and electrons) should be developed with careful consideration of the tradeoffs between pressure and distance to ensure the neutral radicals make it to the substrate for the building of the atomic layer deposition film. To achieve a neutral atomic nitrogen mean free path on the order of inches or centimeters, sufficient for processing, the partial pressure should be around or below the mTorr range (˜10⁻³ Torr) and preferably around or below 10⁻⁴ to 10⁻³ Torr. Processing with electrons as the mean free path limited species will require pressures much lower yet.

The tradeoffs with substrate processing chamber pressure and distance should also be considered with the required partial pressure of the halogen-based (TiCl₄, for example), organometallic (TDMAT—tetrakisdimethylamido titanium, for example), or other precursor comprising Si, Ti, Ta, Hf, Al, etc. to obtain a layer of the precursor on the substrate as the pressure is an essential component of the Langmuir dosage required. Typically reasonable processing times require that precursor partial pressures are around the mTorr range (˜10⁻³ Torr) or higher and more preferably around or above 10⁻³ to 10 Torr with higher precursor partial pressures corresponding to shorter dosage times for a given precursor. Therefore, a system sufficient for processing with mean free path limited species will require a pumping scheme that can reach medium to high or ultrahigh vacuum pressures while also including a device for throttling the pumping system to ensure that the alternate precursors are able to quickly build a suitable partial pressure for a short dosage time.

An additional parameter that should be considered and affects the tradeoff between the mean free path and the partial pressure of the mean free path limited species is the kinetic energy of the species themselves. For instance, it is possible to bias the substrate support system relative to the plasma region in a manner that directs electrons or ions toward it and the substrate, giving these species additional kinetic energy. In a preferred embodiment of the system described herein, the ions with additional kinetic energy would be substantially neutralized as they pass through an aperture plate between the plasma region and the substrate processing chamber and therefore would become neutral radical species with additional kinetic energy, which could allow them to travel further (in effect, increase their mean free path) in a given partial pressure of species with which they could combine or recombine. Lower energy neutral radicals may have kinetic energies ranging from around 0.01 to 0.5 or 1 eV whereas medium energy neutral radicals may have kinetic energies ranging from around 1 to 10 eV, and higher energy neutral radicals may have kinetic energies ranging from around 10 to 100 eV or higher. The system herein and the tradeoffs and limitations discussed can be used to determine an appropriate system configuration for the processing with mean free path limited species with such kinetic energies or higher kinetic energies in the case of electrons (for instance, from around 100 eV to around 20 keV or higher) as the mean free path limited species. Some preferred embodiments would include medium to higher kinetic energies to reduce pumping and throttling challenges and allow for processing to be done at higher pressures closer to those used for the halogen-based, organometallic, or other precursors. Other preferred embodiments are optimized for lower to medium kinetic energies and are not intended to limit the system described herein to such lower to medium kinetic energies of the mean free path limited species.

A system can use mean free path limited species in substrate processing systems. More specifically the system can use mean free path limited species in atomic layer deposition.

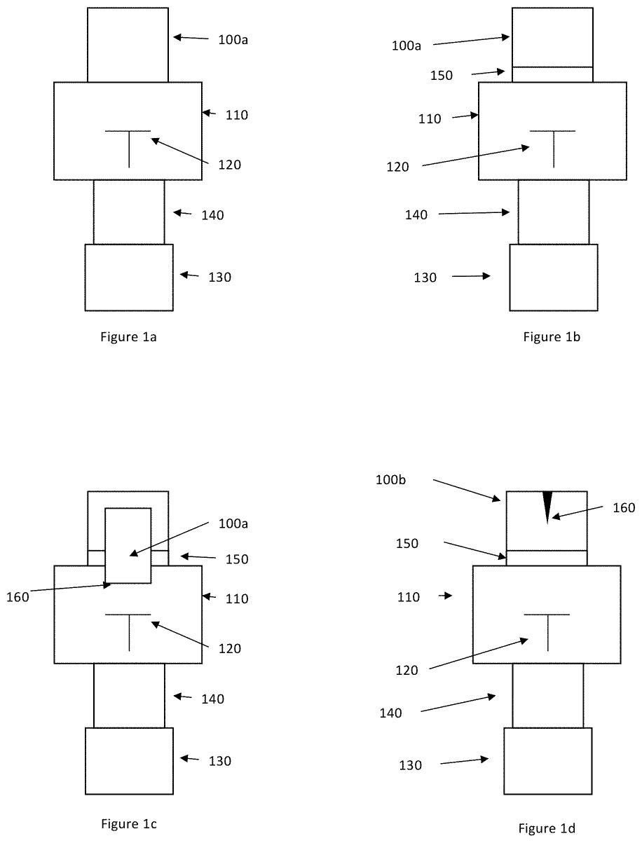

FIG. 1a is a drawing of a preferred embodiment and shows a plasma generation region 100a for generating electrically neutral atomic species, a substrate processing chamber 110, a substrate support system positioned in the chamber 120, a pumping system 130, and a device for throttling the pumping speed 140.

FIG. 1b is a drawing of another preferred embodiment and shows a plasma generation region 100a for generating electrically neutral atomic species, a substrate processing chamber 110, a substrate support system positioned in the chamber 120, a pumping system 130, a device for throttling the pumping speed 140, and a mechanical tuning device 150 for mechanically tuning the distance between the emission point of the mean free path limited species and the substrate.

FIG. 1c is a drawing of another preferred embodiment and shows a plasma generation region 100a for generating electrically neutral atomic species, a substrate processing chamber 110, a substrate support system positioned in the chamber 120, a pumping system 130, a device for throttling the pumping speed 140, and a mechanical tuning device 150 for mechanically tuning the distance between the emission point 160 (“point” can also be a surface as shown herein) of the mean free path limited species and the substrate.

FIG. 1d is a drawing of another preferred embodiment and shows an electron generation region 100a for generating electrons, a substrate processing chamber 110, a substrate support system positioned in the chamber 120, a pumping system 130, a device for throttling the pumping speed 140, and a mechanical tuning device 150 for mechanically tuning the distance between the emission point 160 (“point” refers to a point herein) of the mean free path limited species and the substrate; the electron generation region 100b and the plasma generation region 100a both being examples of a generation region (100, unpictured) for generating mean free path limited species.

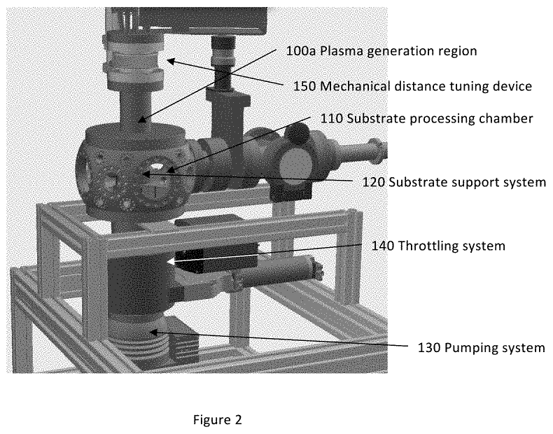

FIG. 2 is a three dimensional mechanical drawing of the preferred embodiment in FIG. 1c and shows a plasma generation region 100a for generating electrically neutral atomic species, a substrate processing chamber 110, a substrate support system positioned in the chamber 120, a pumping system 130, a device for throttling the pumping speed 140, and a mechanical tuning device 150 for mechanically tuning the distance between the emission point of the mean free path limited species and the substrate.

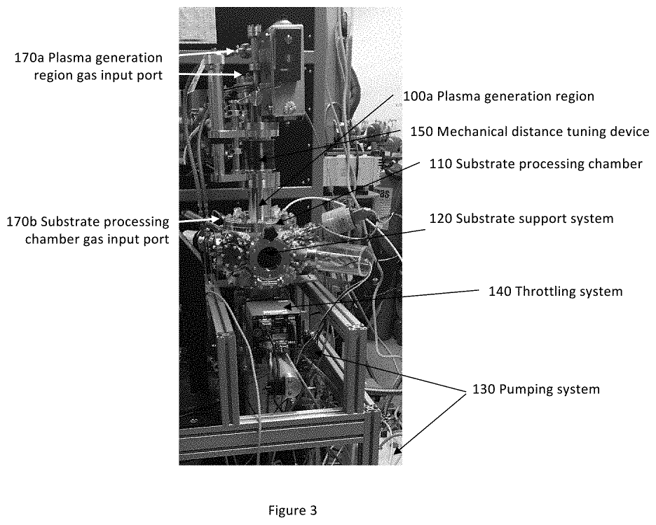

FIG. 3 is a photograph of the preferred embodiment in FIG. 1c and FIG. 2 and shows a plasma generation region 100a for generating electrically neutral atomic species including at least one gas inlet 170a, a substrate processing chamber 110 including at least one gas inlet 170b, a substrate support system positioned in the chamber 120, a pumping system 130, a device for throttling the pumping speed 140, and a mechanical tuning device 150 for mechanically tuning the distance between the emission point of the mean free path limited species and the substrate.

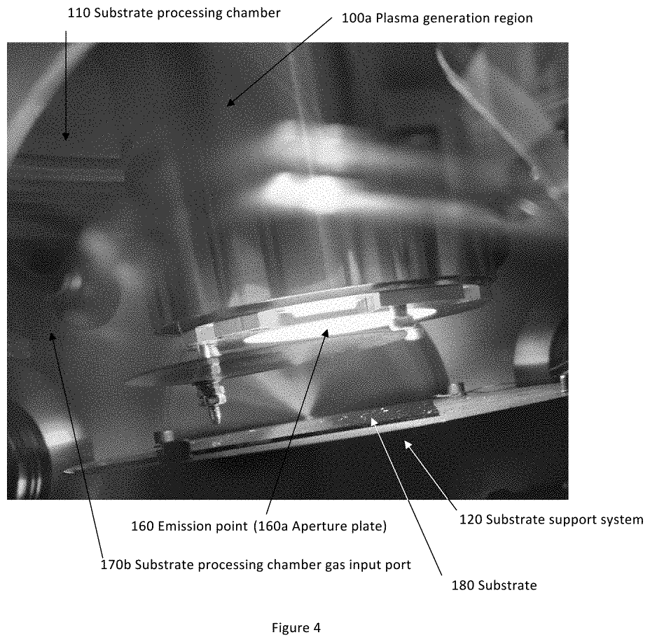

FIG. 4 is a photograph of the interior of the substrate processing chamber 110 of the preferred embodiment in FIG. 1c and FIG. 2 and shows a plasma generation region 100a for generating electrically neutral atomic species including at least one gas inlet 170b, a substrate processing chamber 110, a substrate support system positioned in the chamber 120, the emission point 160 (point can also be a surface as shown herein where the surface is the aperture plate 160a) of the mean free path limited species and the substrate 180.

In the variation of the system shown in FIGS. 3 and 4, the source component comprising an inductively coupled plasma is excited with around 13.56 MHz RF electromagnetic radiation with a power up to 600 W, the inductively coupled plasma including an excitation coil surrounding a pyrolytic boron nitride ceramic tube, the source component also comprising an aperture plate positioned next to a plasma generator, the aperture plate placed between the plasma region, and the substrate the plasma exciting the input and mass flow controlled N₂ and H₂ gases into radicals. The aperture plate providing the electrically neutral radical species comprising N and H into the substrate processing chamber and toward the substrate surface on the heated (usually around or below 300° C.) substrate support system, the aperture plate, serving as the emission point, being tuned to be roughly within one mean free path length of the substrate surface using the mechanical tuning device being an edge welded stainless steel bellows system with a single axis of motion roughly normal to the substrate surface. The electrically neutral radical species comprising H including and neutral atomic hydrogen serving to remove the chlorine ligands from the halogen-based precursor TiCl₄ previously supplied to the substrate processing chamber using a pneumatic pulse valves and carried by the inert gas N₂ supplied to the substrate processing chamber using a mass flow controller, the chemisorbed Ti remaining on the substrate surface after the chlorine ligands are removed. The electrically neutral radical species comprising N including neutral atomic nitrogen binding with the Ti surface species left vacant by the removed chlorine ligands thus building a layer of film comprising TiN. The shown system also containing a pumping system comprising a turbomolecular pump with top pumping speed around 200-300 L/s backed by a roughing pump with top pumping speed around 5-15 L/s pumping on a total volume of around 1-10 L including the substrate processing chamber. The system also including a throttling device comprising a butterfly valve, the butterfly valve being used to adjust the pumping speed and to set the partial pressure (usually around 1-10 mTorr for around or less than 1 s) of the TiCl₄ during the portion(s) of the processing including the TiCl₄ and to set the partial pressure (usually less than around 10⁻³ Torr for less than around 30 s) of the electrically neutral radical species comprising N and H in the portion(s) of the processing including the electrically neutral radical species comprising N and H. The numbers, values, and specifications given herein are not intended to limit the scope of the invention and the ranges in time, pressure, temperature, position, chemical or chemical composition, process flow, etc. but are intended to provide a specific example of a possible system within the set of all possible systems contained within this invention wherein a film can be processed with mean free path limited species. Each film composition may need its own set of parameters for successful deposition.

In one variation, a system for substrate processing with mean free path limited species, can include: a component for generating the mean free path limited species in a generation region; a substrate processing chamber; a substrate support system positioned in the substrate processing chamber, the substrate support system positioned within the mean free path of the mean free path limited species; and/or a pumping device for evacuating the contents of the substrate processing chamber.

In one variation of a system for substrate processing, the system comprising: a generation region that includes a source component that supplies a mean free path limited species; a substrate processing chamber; a substrate support system positioned in the substrate processing chamber, the substrate support system positioned roughly within the mean free path of the mean free path limited species; and a pumping system that evacuates contents of the substrate processing chamber.

In a related variation of a system for substrate processing, where the mean free path limited species comprises one or more of: electrons or an electrically neutral radical species such as neutral atomic hydrogen, neutral atomic nitrogen, neutral atomic oxygen, neutral atomic carbon, neutral atomic sulfur, neutral atomic selenium, neutral atomic fluorine, neutral atomic phosphorus, or another neutral atomic species or a neutral molecular radical containing N, H, C, O, S, Se, F, or P.

In a related variation of a system for substrate processing, where the source component supplies the mean free path limited species, and wherein the source component comprises an aperture plate or screen positioned next to a plasma generator, the aperture plate placed between the plasma region and the substrate.

In a related variation of a system for substrate processing, where plasma-exciting, oscillating electric fields form the neutral radical species and substantially contain the ionized species in the generation region and flowing the neutral radical species through an outlet of the generation region.

In a further variation of a system for substrate processing, where the system further comprises a throttling device that adjusts the pumping speed of the substrate processing chamber.

In a related variation of a system for substrate processing, where the device for throttling the pumping of the substrate processing chamber is used to adjust the pumping speed in a cyclic manner for alternating process steps.

In a related variation of a system for substrate processing, where the throttling device adjusts the partial pressure of the mean free path limited species in the substrate processing chamber such that the species' mean free path is roughly longer than the distance between their emission point and the substrate.

In a further variation of a system for substrate processing, where the system further comprises a mechanical tuning device that adjusts the distance between the emission point of the mean free path limited species and the substrate.

In a related variation of a system for substrate processing, where the pumping system includes a turbomolecular pump, cryogenic pump, ion pump, diffusion pump, or sublimation pump backed by a roughing pump such as a roots pump, rotary vane pump, or another mechanical pump.

In another variation of a system for substrate processing, where the substrate support system is heated and made of a material or coated with a material chosen for process chemistry compatibility and good thermal conductivity and heat transfer to the substrate. Such materials can include but are not limited to substrate support systems made of Cu, Al, Ti, etc. and/or coated with TiN, SiO₂, Al₂O₃, etc. The substrate support system can also be configured for substrate transfer with a substrate transfer device such as a manual load lock transfer arm and fork or a wafer handling robot. The substrate support system can also be electrically isolated, grounded, or set at a desired electrical potential relative to the chamber itself, the plasma, etc.

In another variation of a system for substrate processing, where the substrate support system is electrically isolated, grounded, or set at a desired electrical potential.

In another variation of a system for substrate processing, where the throttling device comprises a butterfly valve, a shutter valve, a vane valve, or another type of throttling valve.

In another variation of a system for substrate processing, where the mechanical tuning device that adjusts the distance between the emission point of the mean free path limited species and the substrate is a bellows system, such as an edge welded stainless steel bellows system, with at least a single axis of motion.

In another variation of a system for substrate processing, where the generation region includes at least one input port for inserting gases for plasma generation; the gases having flow control devices such as pneumatic pulse valves or mass flow controllers.

In another variation of a system for substrate processing, where the generation region includes a source component that generates electrons using a form of electron generation such as from a metallic filament, sharp tip, needle, or nanotube or any form of electron beam generation using a thermionic, field emitter, photoelectric, or plasma source of electrons.

The systems may be used with or otherwise make use of systems and methods described in the following references, the entire contents of each of which are incorporated by reference herein: KR 10-2005-0023782, U.S. Pat. Nos. 8,187,679, 8,637,123B2, 6,605,549B2, 6,638,862, 4,389,973, 5,916,365, 6,200,893, 6,388,383, 6,616,986, 7,798,096, 7,919,142, US20040060657A1, US20110159204A1, US20140272179A1, US20150053259A1, and US20160013020A1.

As a person skilled in the art will recognize from the previous detailed description and from the figures and claims, modifications and changes can be made to the embodiments of the invention without departing from the scope of this invention as defined in the following claims.

What is claimed is:

1. A system for substrate processing, the system comprising:
a generation region that includes a source component that supplies a mean free path limited species;
a substrate processing chamber;
a substrate support system positioned in the substrate processing chamber, the substrate support system positioned roughly within the mean free path of the mean free path limited species; and
a pumping system that evacuates contents of the substrate processing chamber.

2. The system of claim 1 where the mean free path limited species comprises one or more of: electrons or an electrically neutral radical species such as neutral atomic hydrogen, neutral atomic nitrogen, neutral atomic oxygen, neutral atomic carbon, neutral atomic sulfur, neutral atomic selenium, neutral atomic fluorine, neutral atomic phosphorus, or another neutral atomic species or a neutral molecular radical containing N, H, C, O, S, Se, F, or P.

3. The system of claim 2 where the source component supplies the mean free path limited species, and wherein the source component comprises an aperture plate or screen positioned next to a plasma generator, the aperture plate placed between the plasma region and the substrate.

4. The system of claim 2 where plasma-exciting, oscillating electric fields form the neutral radical species and substantially contain the ionized species in the generation region and flowing the neutral radical species through an outlet of the generation region.

5. The system of claim 1 where the system further comprises a throttling device that adjusts the pumping speed of the substrate processing chamber.

6. The system of claim 5 where the device for throttling the pumping of the substrate processing chamber is used to adjust the pumping speed in a cyclic manner for alternating process steps.

7. The system of claim 5 where the throttling device adjusts the partial pressure of the mean free path limited species in the substrate processing chamber such that the species' mean free path is roughly longer than the distance between their emission point and the substrate.

8. The system of claim 1 where the system further comprises a mechanical tuning device that adjusts the distance between the emission point of the mean free path limited species and the substrate.

9. The system of claim 1 where the pumping system includes a turbomolecular pump, cryogenic pump, ion pump, diffusion pump, or sublimation pump backed by a roughing pump such as a roots pump, rotary vane pump, or another mechanical pump.

10. The system of claim 1 where the substrate support system is heated and made of a material or coated with a material chosen for process chemistry compatibility and good thermal conductivity and heat transfer to the substrate.

11. The system of claim 1 where the substrate support system is electrically isolated, grounded, or set at a desired electrical potential.

12. The system of claim 5 where the throttling device comprises a butterfly valve, a shutter valve, a vane valve, or another type of throttling valve.

13. The system of claim 8 where the mechanical tuning device that adjusts the distance between the emission point of the mean free path limited species and the substrate is a bellows system, such as an edge welded stainless steel bellows system, with at least a single axis of motion.

14. The system of claim 2 where the generation region includes at least one input port for inserting gases for plasma generation; the gases having flow control devices such as pneumatic pulse valves or mass flow controllers.

15. The system of claim 2 where the generation region includes a source component that generates electrons using a form of electron generation such as from a metallic filament, sharp tip, needle, or nanotube or any form of electron beam generation using a thermionic, field emitter, photoelectric, or plasma source of electrons.
